(19) United States
(12) Patent Application Publication
(10) Pub. No.: US 2018/0108554 A1
(43) Pub. Date: Apr. 19, 2018

(54) METHOD FOR SELF-ALIGNING A THIN-FILM DEVICE ON A HOST SUBSTRATE

(71) Applicants: Research Foundation of the City University of New York, New York, NY (US); Hunan University, Changsha (CN)

(72) Inventors: Jing Xiao, Changsha (CN); Ritesh Ray Chaudhuri, New York, NY (US); Xiaolong Liu, Changsha (CN); Sang-Woo Seo, Fort Lee, NJ (US)

(21) Appl. No.: 15/783,236

(22) Filed: Oct. 13, 2017

Related U.S. Application Data
(60) Provisional application No. 62/408,298, filed on Oct. 14, 2016.
(60) Provisional application No. 62/529,227, filed on Jul. 6, 2017.

(51) Int. Cl. H01L 21/68; H01L 21/683; H01L 31/0304; H01L 33/30; B32B 7/12; B32B 7/02; B32B 37/12; B32B 43/00

(52) U.S. Cl. CPC H01L 21/68; H01L 21/6835; H01L 31/0304; H01L 33/30; B32B 7/12; B32B 7/02; B32B 2311/00; B32B 43/006; B32B 2457/14; B32B 2307/20; B32B 2307/40; B32B 2313/00; B32B 37/12

(57) ABSTRACT

A method for self-aligning a thin-film device on a host substrate is provided. A predetermined location on a host substrate is treated with a hydrophobic lubricant to alter its interfacial energy. A needle is used to transfer a thin-film device, under water, to the location. Upon contact with the lubricant, the device adheres and self-aligns to the location to minimize the interfacial energy.

### CROSS-REFERENCE TO RELATED APPLICATIONS

This application claims priority to and is a non-provisional of U.S. Patent Applications 62/408,298 (filed Oct. 14, 2016) and 62/529,227 (filed Jul. 6, 2017), the entirety of which are incorporated herein by reference.

### STATEMENT OF FEDERALLY SPONSORED RESEARCH OR DEVELOPMENT

This invention was made with government support under grant number EEC-0823793 awarded by the National Science Foundation. The government has certain rights in the invention.

The applicants also wish to thank the National Natural Science Foundation of China (grant numbers 61404047 and 61501179), the China Scholarship Council and the Natural Science Foundation of Hunan Providence, China (grant number 2015JJ3034).

### BACKGROUND OF THE INVENTION

One of the challenges in integrated microsystems is the development of multimaterial systems with new functionalities. Heterogeneous integration techniques offer the capability of combining various materials and devices, for instance, optics, electronics, and microfluidics, onto a preprocessed host substrate. Among the demonstrated techniques, fluidic self-assembly (FSA) is widely used for heterogeneous integration because it provides effective self-alignment and parallel manipulation of micro/millimeter scale devices, which are realized in their preferential growth substrates through specific fabrication procedures. However, one of the challenges to be solved in FSA due to its stochastic nature is that the devices might not reach the desired integration locations. In other words, an efficient external guiding mechanism is essential to steer the devices to their predefined binding sites. To address this issue, different guiding mechanisms such as pulsating flow, ultrasonic vibration, magnetic field and electric field have been studied.

The FSA approach with an efficient external guiding mechanism benefits parallel integration especially for highly dense microsystems. However, most of the demonstrated devices are thick and bulky compared with thin-film devices having a thickness of 0.8-3 μm.

On the other hand, the pick-and-place (PAP) approach is comparatively straightforward and useful for a microsystem that does not require massive and dense integration. It can correct the stochastic limitation of the self-assembly process and provide the potential of dexterous manipulation and complex operations with the help of advanced robotic kinematics and automation strategies. However, with the decrease in device dimensions, the conventional PAP method requires modification. For instance, its requirements include safe handling of the devices and tackling the sticking problem during the device releasing step. Compared to a thin-film device, most of the reported devices integrated utilizing PAP and capillarity are thick in nature. Therefore, the risk of damaging them in the storage and handling steps is low.

The discussion above is merely provided for general background information and is not intended to be used as an aid in determining the scope of the claimed subject matter.

### BRIEF DESCRIPTION OF THE INVENTION

A method for self-aligning a thin-film device on a host substrate is provided. A predetermined location on a host substrate is treated with a hydrophobic lubricant to alter its interfacial energy. A needle is used to transfer a thin-film device, under water, to the location. Upon contact with the lubricant, the device adheres and self-aligns to the location to minimize the interfacial energy.

In a first embodiment, a method for self-aligning a thin-film device on a host substrate is provided. The method comprises steps of: preparing a host substrate by depositing a first hydrophobic lubricant on at least one predetermined location on the host substrate; releasing a thin-film device under water from a carrier substrate, wherein the thin-film device is attached to the carrier substrate by a water-soluble polymer; picking up the thin-film device with a hydrophobic needle having a second hydrophobic lubricant at a tip of the hydrophobic needle; moving, while in a water environment, the hydrophobic needle with the thin-film device to the host substrate and contacting the thin-film device to the first hydrophobic lubricant on the predetermined location of the host substrate, the step of moving occurring with the thin-film device, the host substrate and the hydrophobic needle are under water; permitting the thin-film device to adhere and self-align with the predetermined location due to interfacial energy minimization; and evaporating the hydrophobic lubricant.

In a second embodiment, a method for self-aligning a thin-film device on a host substrate is provided. The method comprising steps of: preparing a host substrate by depositing a hydrophobic lubricant on at least one predetermined location on the host substrate; picking up the thin-film device with a magnetic needle; moving, while in a water environment, the magnetic needle with the thin-film device to the host substrate, and contacting the thin-film device to the hydrophobic lubricant on the predetermined location of the host substrate, the step of moving occurring with the thin-film device, the host substrate and the magnetic needle are under water; permitting the thin-film device to adhere and self-align with the predetermined location due to interfacial energy minimization; and evaporating the hydrophobic lubricant.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of the invention. In the drawings, like numerals are used to indicate like parts throughout the various views. Thus, for further understanding of the invention, reference can be made to the following detailed description, read in connection with the drawings in which:

FIG. 1 is a perspective view of one system for implementing the disclosed method;

FIG. 2A to FIG. 2H are optical images of various steps of the disclosed method;

FIG. 3A to FIG. 3C are optical images showing a thin film device auto-aligning to a integration pads due to minimization of interfacial energy;

FIG. 4A to FIG. 4H are schematic images of a method preparing a thin-film photonic device;

FIG. 5A and FIG. 5B shows a side view of the photonic device before and after wax removal while FIG. 5C and FIG. 5D show a top view before and after wax removal;

FIG. 5E shows the photonic device before releasing to the host cover glass and FIG. 5F shows the photonic device after releasing;

FIG. 5G to FIG. 5J are optical images showing the gradual release of photonic devices in fluidic medium utilizing water-soluble polymer;

FIG. 5K and FIG. 5L shows the photonic device being detached from the glass cover;

FIG. 6A to FIG. 6F are schematic side views of various steps of integration substrate preparation in the disclosed method while FIG. 6G shows lubricant formed only on the predetermined integration pads;

FIG. 7A to FIG. 7D are optical images of a needle tip showing the formation of a lubricant droplet at the needle tip;

FIG. 8A is a top view of an array of integrated thin-film devices while FIG. 8B, FIG. 8C, FIG. 8D and FIG. 8E are graphs depicting measured current versus applied voltage for the four devices;

FIG. 9 is a graph depicting alignment of the four devices relative to its optimal integration location;

FIG. 10A depicts a test device to measure contact resistance while FIG. 10B depicts measured resistances of the integrated test device;

FIG. 11A is a depict of a system for aligning a thin film device on a host substrate; FIG. 11B shows a magnetized needle picking up a thin-film device; FIG. 11C shows the needle moving the device to a target location; FIG. 11D shows the device after placement;

FIG. 12A graphically depicts distribution of magnetic flux density of a needle while FIG. 12B is a graph depicting magnetic flux density distribution along needle tips of different shapes;

FIG. 13A to FIG. 13F are schematic depicts of steps involved in forming a thin-film device;

FIG. 13G to FIG. 13K are optical images of selected thin-film devices;

FIG. 14A to FIG. 14F are schematic depictions of a method for modifying host substrates while FIG. 14G and FIG. 14H are images showing modification of host surface (FIG. 14G) and lubricant formed only on the binding sites (FIG. 14H);

FIG. 15A to FIG. 15H are optical images showing the use of a magnetized needle to place a thin-film device at a target location;

FIG. 16A to FIG. 16F to optical images showing self-alignment of a thin-film device upon intentional displacement;

FIG. 17 is a SEM micrograph of a thin-film device;

FIG. 18 is a graph of measures current versus applied voltage that verifies the electrical contact of the integrated device and substrate;

FIG. 19 is a graph showing the stability of magnetic flux density over time;

FIG. 20A and FIG. 20G are optical images of a magnetized needle tip with different flux densities manipulating a device;

FIG. 21A to FIG. 21D are schematic depicts of a method of releasing a thin film device while FIG. 21E to FIG. 21H are optical images of the thin-film device detaching due to treatment with water;

FIG. 22 provides various images of a magnetized needle picking up thin-film devices;

FIG. 23A is a depiction of a system used to model the attachment method; FIG. 23B is a graph of surface energy versus lubricant volume;

FIG. 23C is a graph of restoring force versus height-offset;

FIG. 24 depicts variation of attractive magnetic force with magnet flux density for a particular needle;

FIG. 25A is a graph of capillary restoring force as a function of lateral displacement; FIG. 25B depicts various offsets of the device; and

FIG. 26 depicts a hydrodynamic force analysis of the device in water.

### DETAILED DESCRIPTION OF THE INVENTION

This disclosure demonstrates the integration of thin-film photonic devices onto a silicon-based host substrate utilizing surface tension-driven FSA and a modified micro-PAP approach. The thin-film format of optical devices allows a topological flat surface after its integration. This leads to a unique advantage: layer-by-layer integration.

The disclosed integration approach provides exciting opportunities for heterogeneous integration of thin-film devices with high repeatability and improved process yield.

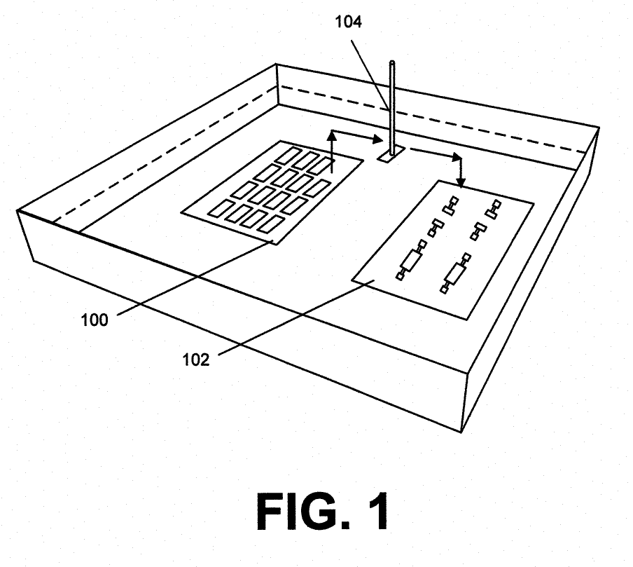

FIG. 1 shows the disclosed integration approach of thin-film III-V optical devices onto a silicon substrate. Thin-film III-V optical devices are fabricated and transferred onto a temporary carrier 100 (e.g. a glass cover) in water, making them ready for further integration. Also, a silicon host substrate 102 with electrical contacts is prepared and an attracting lubricant medium for self-assembly is selectively formed on their predesigned integration locations. A needle tip 104 is treated to be hydrophobic to attract the lubricant. This allows the needle tip to pick up a thin-film device sitting on the temporary carrier in water. Then, the needle tip with the thin-film device is brought to the integration substrate and roughly aligned with the binding sites. The needle tip is lowered to make the thin-film device contact the attractive lubricant predefined on the integration pads. The thin-film device is released from the needle tip due to a more significant attraction force between the thin-film device and the lubricant on the silicon host substrate. Once the thin-film device is attracted by the lubricant, it achieves self-alignment due to interfacial energy minimization and completes the integration.

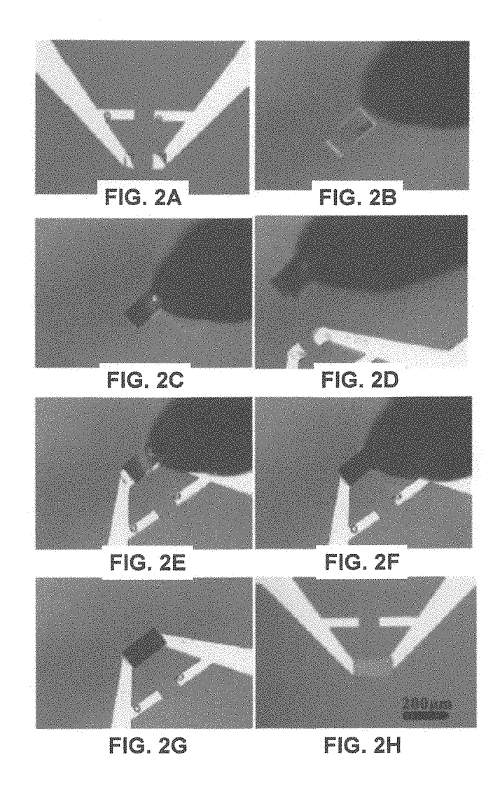

In one embodiment a SiO₂/Si host substrate was prepared with selective formation of lubricant on binding sites as shown in FIG. 2A to FIG. 2H. In FIG. 2A a lubricant is selectively formed on the integration pads of a silicon host substrate in a water environment. In FIG. 2B and FIG. 2C a thin-film GaAs photonic device (PD) picked up by a needle with lubricant on its tip. In FIG. 2D a needle is moved close to the integration area. In FIG. 2E the needle is roughly aligned with the integration pads and lowered to contact the lubricant. In FIG. 2F both sides of the PD are in contact with the lubricant and detached from the needle. FIG. 2G shows the integrated PD in water. FIG. 2H depicts the integrated PD after postprocessing.

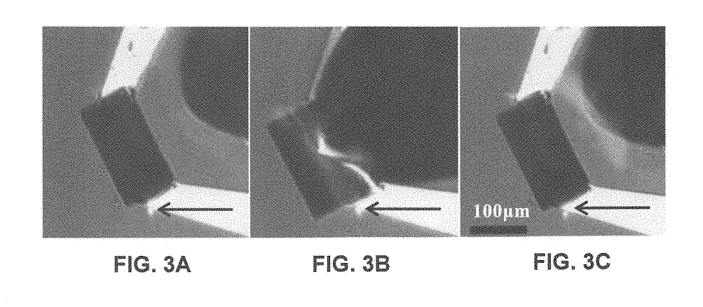

Captured pictures in FIGS. 3A to 3C demonstrate the self-alignment capability of the disclosed integration method. A needle was used to move an integrated PD to create an offset from the initial integrated position (FIG. 3A and FIG. 3B). After releasing the needle (see FIG. 3C), the PD moved back to the original location due to the minimization of interfacial energy (see FIG. 3C). Finally, the water was drained out and the host substrate was placed in an oven to evaporate the lubricant completely (see FIG. 2H). A polymer was spun on the top of the PD and cured to achieve a stable metal-to-metal contact due to thermo-compression. Next, the polymer was removed by oxygen (O₂) plasma. The electrical measurement of the integrated PD can be done to verify the contact of the PD and substrate. This demonstrates the feasibility of the disclosed integration method. The details of thin-film PD fabrication, host substrate preparation, needle tip treatment, and an array integration of thin-film PDs are described in the following sections.

Thin-Film PD Fabrication

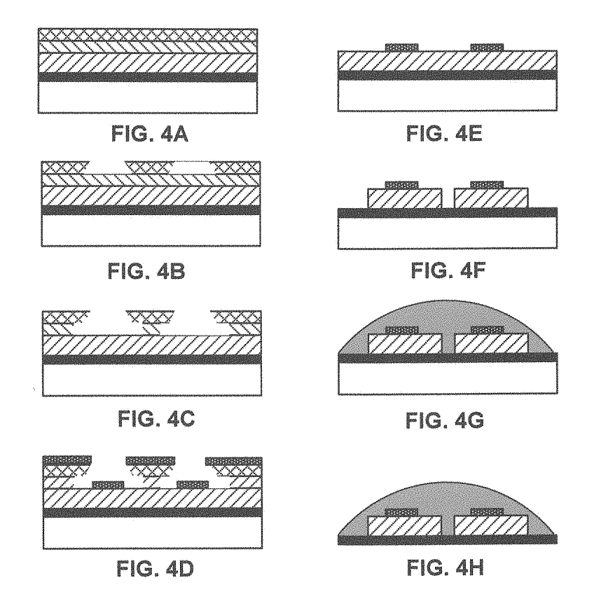

The GaAs metal-semiconductor-metal (MSM) PDs are separately grown, optimized, and fabricated on their preferred growth substrate. The material structure of the starting wafer is as follows: GaAs PD layer/AlAs etching stop layer/GaAs growth substrate with thicknesses of 1/0.2/350 μm, respectively. The top metal patterning with Cr\Au (20\180 nm) was done with a bilayer lift-off process, which includes SF11 and AZ photoresists lithography and thermal evaporation, as shown in FIGS. 4A to 4E. FIG. 4A shows the GaAs wafer with photoresists. FIG. 4B depicts AZ5214 exposure. FIG. 4C depicts SF11 exposure. FIG. 4D illustrates metal deposition by thermal evaporation. FIG. 4E shows the devices after lift-off. After the mesa definition by wet etching using citric acid:H₂O₂ (4:1) (see FIG. 4F), the thin-film PDs were separated from the growth substrate by the removal of the sacrificial layer (AlAs) using hydrofluoric acid (HF, 10%). In FIG. 4G and FIG. 4H the thin-film PDs were embedded in and protected by APIEZON® wax.

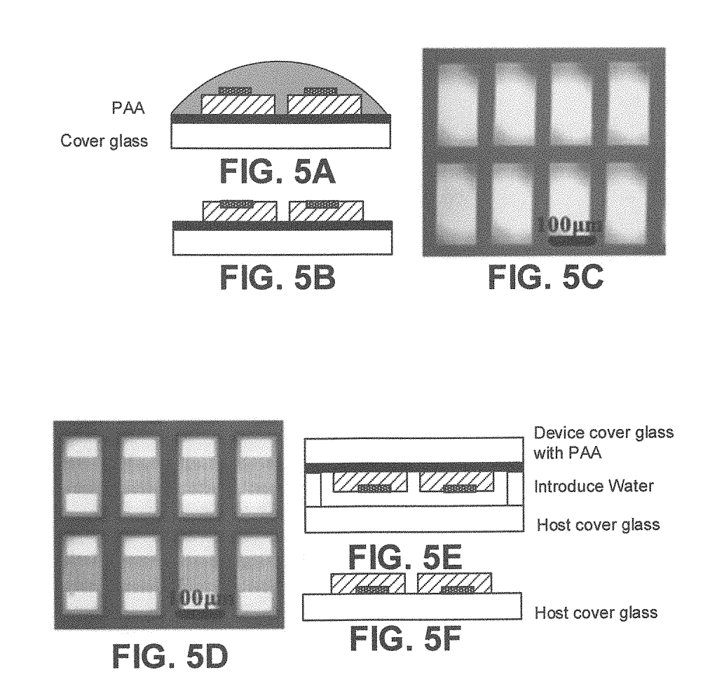

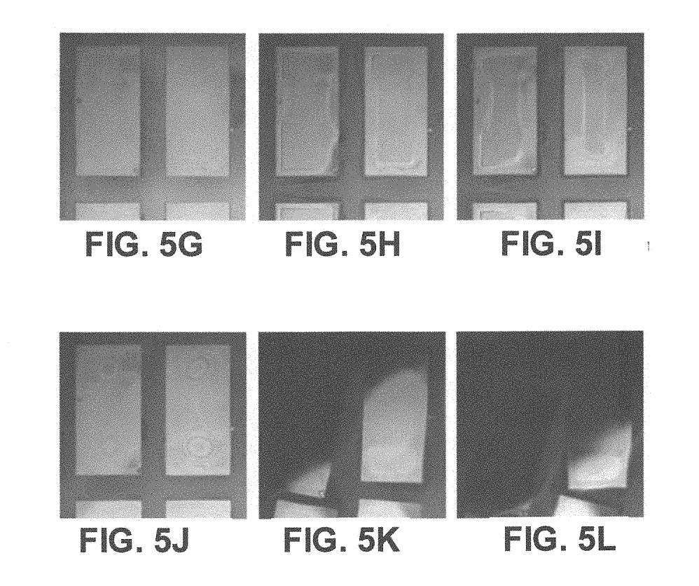

A droplet of a solution comprising 25% polyacrylic acid (PAA) and water (1:3 v/v) was dispensed onto a cover glass, and the PDs were placed on top of the PAA overnight (see FIG. 5A). Later, the wax was removed by trichloroethylene (FIG. 5B), and the sample is shown in FIG. 5C and FIG. 5D. The thin-film PDs on the PAA were transferred to another cover glass with their metal side facing down for future integration. The setup is illustrated in FIG. 5E. The glass with PAA and PDs was flipped over and mounted on the top of the final host cover glass in a Petri dish. The gap between the device cover glass and the host cover glass was generated by two cover glasses (the gray pillar in FIG. 5E), which resulted in a 200-μm gap. DI water was then introduced with a pipette to the Petri dish to dissolve the PAA (FIG. 5G, FIG. 5H, FIG. 5I and FIG. 5J), and thus PDs got detached from the upper cover glass (FIG. 5K and FIG. 5L). The PDs were saved and stored on the host cover glass in water environment for the disclosed integration approach.

Host Substrate Preparation and Selective Formation of Lubricant

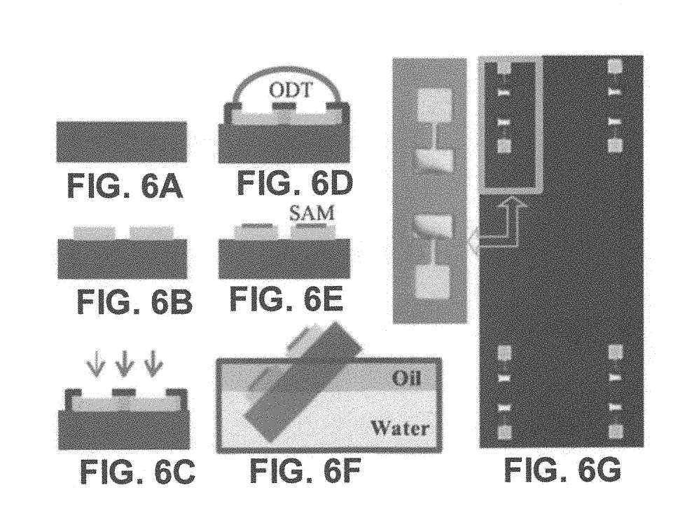

SiO₂ (1 μm)-coated silicon wafer was employed as a host substrate (FIG. 6A). The electrical contacts (Cr\Au, 20\180 nm) were patterned using a bilayer lift-off process (FIG. 6B). The same bilayer photolithography was used to open the integration pads on the substrate, and it was treated with O₂ plasma to modify the surface making it highly hydrophilic, which is preferable for the following self-assembled monolayer (SAM) formation (FIG. 6C). The sample was covered by 1 mM ODT solution (1-octadecane-thiol in ethanol, CH₃(CH₂)₁₇SH) for 1 min (FIG. 6D). Other aliphatic thiols may also be suitable. Other suitable examples include 1H,1H,2H,2H-perfluorodecanethiol (PFDT) and the like. See J. Mater. Chem., 2005, 15, 1523-1527 for further guidance. One terminal of the chemical adheres well onto the hydrophilic gold surface while the other terminal is hydrophobic. The photoresist was removed by immersion in PG remover, and the substrate was cleaned with acetone, methanol, and isopropyl alcohol, and dried with nitrogen (N₂) (FIG. 6E). The substrate was lowered into a Petri dish through the lubricant-water interface (FIG. 6F). FIG. 6G shows that the lubricant formed only on the integration pads (rectangle pads), which were opened by photolithography. The lubricant used is an evaporable solvent, OPTICLEAR® S2 (National Diagnostics) which is hydrocarbon blend based optical degreaser (CAS 64742-47-8), and it leaves no residue after evaporation. This benefits the direct metal-to-metal bonding between the thin-film device and integration pads to achieve permanent electrical contact. Also it evaporates more slowly compared with other solvents, providing stability in terms of device alignment.

Treatment of the Needle and an Array Integration of the Thin-Film PDs

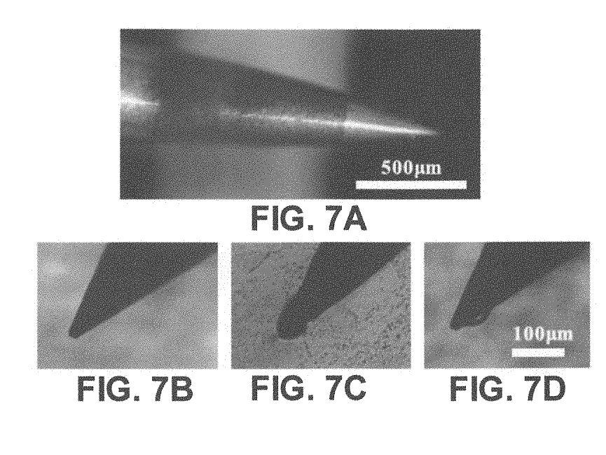

A needle used for PD integration was prepared by depositing Cr\Au (20\180 nm) on its tip area using thermal evaporation and KAPTON® tape. After peeling off the tape, only the tip area was coated with gold (FIG. 7A). The needle was treated with O₂ plasma (hydrophilic surface) and dipped into ODT solution to form the SAM on the gold area. This process changes the gold tip into a hydrophobic surface, which promotes exclusive lubricant formation in the tip area. The needle was attached to a micromanipulator for optimum pick-up and transportation of the device (see FIG. 7B). The needle was introduced in water environment and brought in contact with the lubricant droplet (FIG. 7C), which resulted in the formation of a small lubricant droplet at the tip, as shown in FIG. 7D.

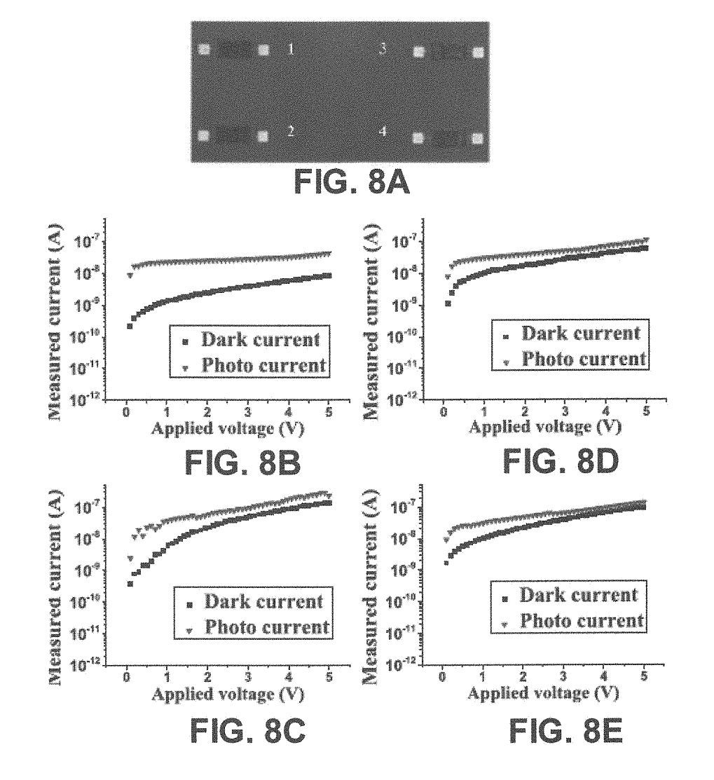

The needle was used to pick up one PD from the fabricated GaAs PD array on the cover glass and was coarsely aligned with the binding sites using the same PAP method as described elsewhere in this specification. During picking up the thin-film PDs, the needle tip was carefully lowered to avoid damage to the PDs caused by excessive pressure. Once the PD touched the lubricant on the integration pads with coarse alignment, the needle was moved up and the PD became attracted by the larger amount of lubricant on the substrate. Due to the interfacial energy minimization, the PD was self-aligned onto the integration locations. Before picking up another PD from the array, the needle touched the lubricant again to form the attracting medium. A 2×2 array of the integrated thin-film PD was completed by repeating the PAP steps. Postprocessing was carried out to ensure the stable electrical contact between the PD and its substrate. The OPTICLEAR® S2, which served as the attracting medium in both guiding and self-assembly, can be easily evaporated with little effect on the PD and substrate. The array of integrated thin-film GaAs PDs on the silicon substrate is shown in FIG. 8A and their electrical contact was confirmed by dark current and photocurrent measurements, as shown in FIGS. 8B to 8E. FIG. 8B, FIG. 8C, FIG. 8D and FIG. 8E corresponding to PD1, PD2, PD3 and PD4 (see FIG. 8A) respectively. The variation in the dark currents of the integrated devices might have resulted from fabrication imperfections introduced in the PD fabrication steps.

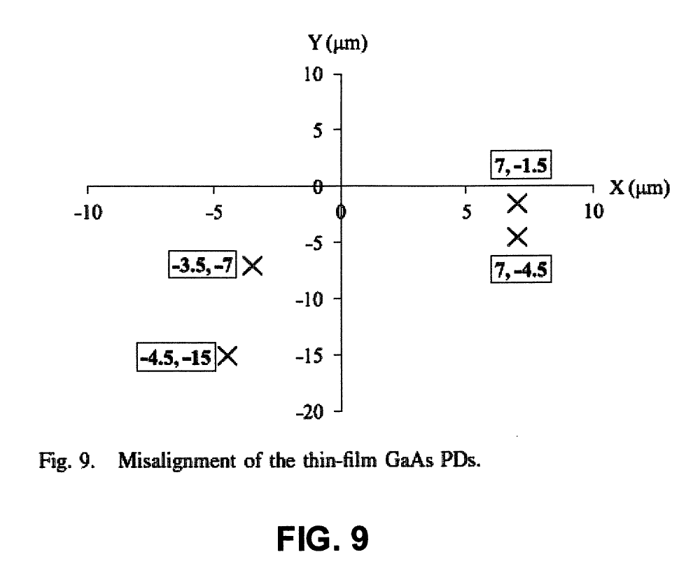

The alignment tolerance of the integrated PDs was also studied. In FIG. 9, each marker represents the point with misalignment of a device from its optimal integration location. The absolute value of the data was employed to calculate the mean and standard deviation of the misalignment, and the results are 5.5 μm±1.78 μm and 7 μm±5.79 μm for x and y axes, respectively. To achieve a more precise alignment of the PD on the desired locations, various parameters should be carefully considered and designed. For example, these include the volume and viscosity of the lubricant, the surface treatment, and the shape and quality of the integration pads. As shown in FIG. 6G, some binding sites were not fully covered by the lubricant (the corner of lower-left side) due to rectangular shape, and the lubricant coverage was not symmetrical to each other. This would affect the final accuracy of device integration. It can be improved by designing different shapes of binding sites or adding thin wetting sidewall for the sites assuring full lubricant coverage. Another reason for misalignment of tiny thin devices might be the shrinking surface tension of water during the water removal step after the self-assembly is completed. More care should be taken to homogeneously extract water from the integration environment. Table 1 represents a comparison of different parameters of the demonstrated integration techniques with relevant published works. It can be seen from the table that most of the published integrated devices are thicker compared with thin-film devices. As the thin-film PDs are very prone to incur physical damage, water-dissolvable polymer and modified PAP were utilized in the device introduction and manipulation steps, respectively, to ensure safe handling.

TABLE 1

| | | | | | Mis- | |
|---|---|---|---|---|---|---|
| Work | Dimension | Introduction | Manipulation | Integration | alignment | |
| 1 | 800 μm × | Nickel based | Confinement | Fluidic | 2 | μm |
| | 280 μm × | confinement | mask and | self- | | |
| | 120 μm | mask | optical | assembly | | |
| | | | mount | | | |
| 2 | 3 mm × | — | — | Capillary | <2 | μm |
| | 350 μm × | | | self- | | |
| | 200 μm | | | assembly | | |
| 3 | 2 mm × | Manual | Manual | Fluidic | 20 | μm |
| | 2 mm × | vacuum | vacuum | self- | | |
| | 125 μm | tweezer | tweezer | assembly | | |
| 4 | Micro- | Elastomeric | Elastomeric | Capillary | | |
| | sphere | membrane | membrane | self- | | |
| | (D) 2 mm | and capillary | | assembly | | |
| | | force | | | | |
| 5 | 200 μm × | UV curable | Surface | Surface | 15 | μm |
| | 400 μm × | polymer and | tension | tension | | |
| | 120 μm | optical fiber | | based | | |
| | | | | self- | | |
| | | | | assembly | | |

| | | | | | |
|---|---|---|---|---|---|
| 6 | 600 μm × | Water | Water | Fluidic | — |
| | 900 μm × | hanging | hanging at | self- | |
| | 70 μm | at the tip | the tip of a | assembly | |
| | | of a | capillary | | |
| | | capillary | | | |
| This | 200 μm × | Water | Modified | Surface | X: 5.5 μm ± |
| work | 100 μm × | dissolvable | PAP tool | tension | 1.78 μm |
| | 1 μm | polymer | | based | Y: 7.0 μm ± |
| | | | | self- | 5.79 μm |
| | | | | assembly | |

1) B. P. Singh, K. Onozawa, K. Yamanaka, T. Tojo, and D. Ueda, “Novel high precision optoelectronic device fabrication technique using guided fluidic assembly,” Opt. Rev., vol. 12, no. 4, pp. 345-351, July 2005.
2) Y. Ito et al., “Vertical-cavity surface-emitting laser chip bonding by surface-tension-driven self-assembly for optoelectronic heterogeneous integration,” Jpn. J. Appl. Phys., vol. 54, no. 3, p. 030206, 2015.
3) G. Arutinov et al., “Capillary self-alignment of mesoscopic foil com- ponents for sensor-systems-in-foil,” J. Micromech. Microeng., vol. 22, no. 11, p. 115022, 2012.
4) G. Fantoni, H. N. Hansen, and M. Santochi, “A new capillary gripper for mini and micro parts,” CIRP Ann.-Manuf. Technol., vol. 62, no. 1, pp. 17-20, 2013
5) A. Suzuki et al., “Self-alignment of optical devices with fiber for low- cost optical interconnect modules,” IEEE Photon. Technol. Lett., vol. 20, no. 3, pp. 193-195, Feb. 1, 2008.
6) K. Bock, S. Scherbaum, E. Yacoub-George, and C. Landesberger, “Selective one-step plasma patterning process for fluidic self-assembly of silicon chips,” in Proc. 58th Electron. Compon. Technol. Conf., May 2008, pp. 1099-1104.

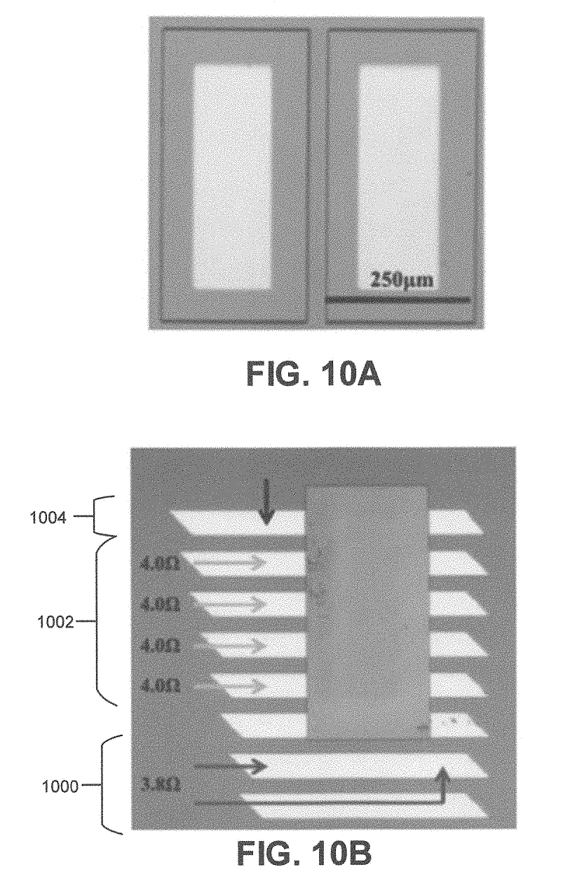

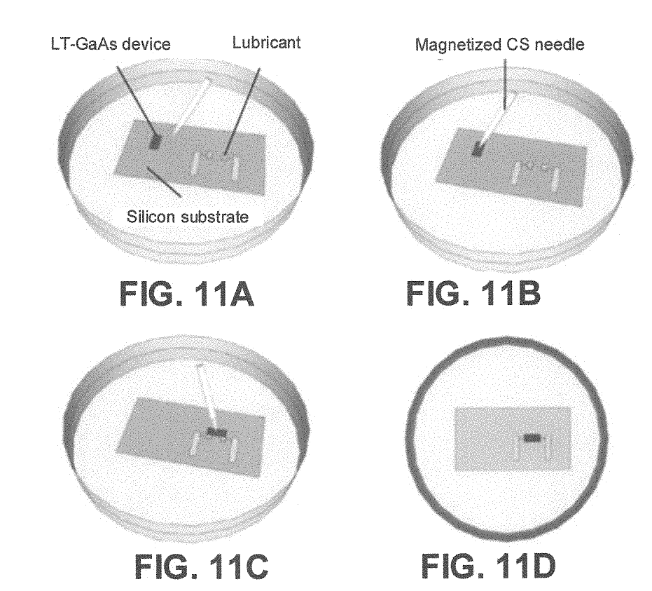

The Au—Au contact resistance between the device pads and integration pads was studied. The test device, substrate, and integrated device are shown in FIG. 10A and FIG. 10B. The fabrication and integration are the same as those described elsewhere in this specification. The test device has metal layers Au/Cr (200/20 nm) with a dimension of 400 μm×150 μm and mesa definition of 500 μm×250 μm (FIG. 10A). The integration host substrate has several 50-μm-wide evaporated metal lines having 30-μm separation between them. The 1 mM ODT solution produced a SAM layer on the selective gold areas, and the lubricant was formed to complete the device integration, followed by post-processing to ensure the Au—Au bonding (FIG. 10B). At first, contact resistance measurements were performed using two probes on a specific metal line (arrows 1000 in FIG. 10B) of the integration substrate to compensate for the test wire resistance and serve as a reference. The effect of the measured value of 3.8 ohms should be eliminated while analyzing the actual gold pad-to-pad contact resistance. After that, contact resistance data were gathered at different locations (arrows 1002 in FIG. 10B) of the integration pad while keeping one of the probes fixed at the base metal line (arrow 1004 in FIG. 10B).

All of the measurements resulted in a resistance of 4.0 ohms. The actual resistance in each of the two gold contacts between the device and the host substrate was experimentally found out to be 0.1 ohms while taking into account the effects of the reference measurements (arrows 1000). As each of the contacts has an area of 50 μm×150 μm, the specific contact resistance can be calculated to be 7.5×10⁻⁶ ohms per cm², which is acceptable compared with reported values.

In this disclosure a technique to heterogeneously integrate thin-film photonic devices on a silicon-based host substrate was demonstrated. Surface tension-driven FSA and micromanipulator-based modified PAP method were used as device integration and guiding mechanisms, respectively. This enables the efficient handling and precise alignment of thin-film photonic devices. GaAs-based thin-film MSM PDs were fabricated in their preferential growth substrate through their specific fabrication procedures. Detailed description of different steps starting from the host substrate preparation, PD release using water-dissolvable polymer, and modification of the PAP tool have been provided along with the fabrication of thin-film GaAs-based MSM PDs. Electrical measurements were performed on the integrated PDs to confirm the functionality of the disclosed integration technique. Thin-film PDs self-aligned to the predefined binding sites on their host substrate due to free energy minimization. This technique opens new avenues for the development of multifunctional photonic systems consisting of multimaterial sub-blocks realized and optimized in their suitable growth substrates and fabrication protocols.

Magnetic Field Based (MFB) Pick-And-Place (PAP) Method

FIGS. 11A to 11D shows the integration approach of a thin-film low-temperature (LT) grown GaAs device onto a silicon host substrate in water environment. A properly magnetized carbon steel (CS) needle tip is employed to pick up thin-film device having an evaporated nickel layer (FIG. 11A and FIG. 11B). The device is manipulated inside the fluidic environment and coarsely aligned with pre-defined binding sites by controlling the movement of the magnetized needle (FIG. 11C). The device is released from the needle tip due to strong capillary force and self-aligns onto its designed optimal integration location due to interfacial energy minimization (FIG. 11D).

Magnetized Carbon Steel Needle Tip

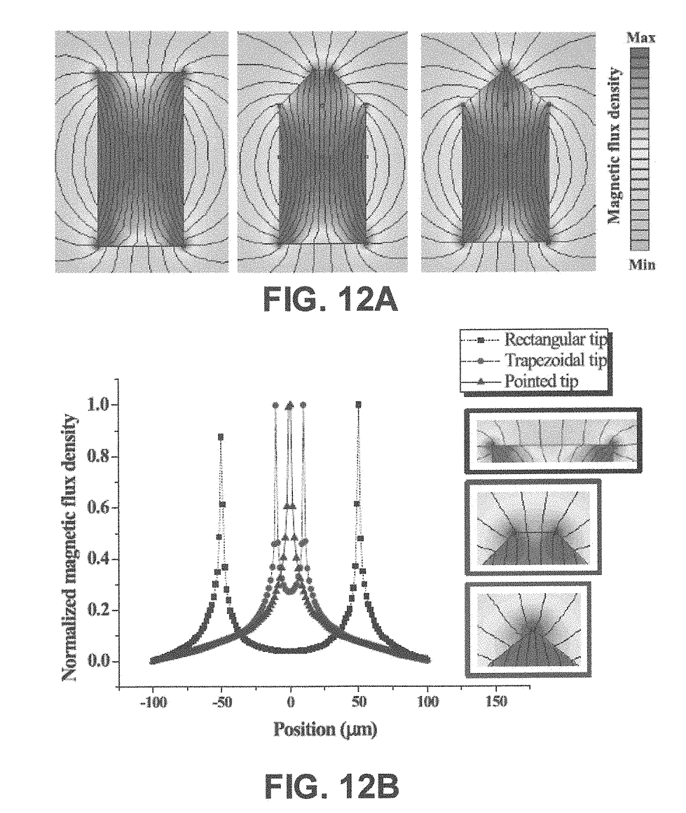

A carbon steel (CS) needle tip (TED PELLA, INC.) was employed to pick up, transport, and place III-V thin-film devices in water environment. With a cylindrical permanent magnet (N52, NdFeB from K&J Magnetics, with dimensions ⅛″× 1/16″) adhering to it for several days, the CS needle was magnetized. After taking out the magnet, the magnetized needle was mounted into a micromanipulator. FIG. 12A and FIG. 12B represent the simulated magnetic flux density distribution of CS needle tips having different tip geometries. Three needle tip geometries were considered for the simulation: rectangular tip (width 100 μm), trapezoidal tip (width 20 μm), and pointed tip. From the simulated results in FIG. 12A and FIG. 12B one can see the induced magnetic flux gets more focused with decreasing dimensions of the needle tip region. As a result, stronger and more localized magnetic field can be obtained at the needle tip aiding the efficient pick-up of thin-film devices.

Thin-Film Device Fabrication

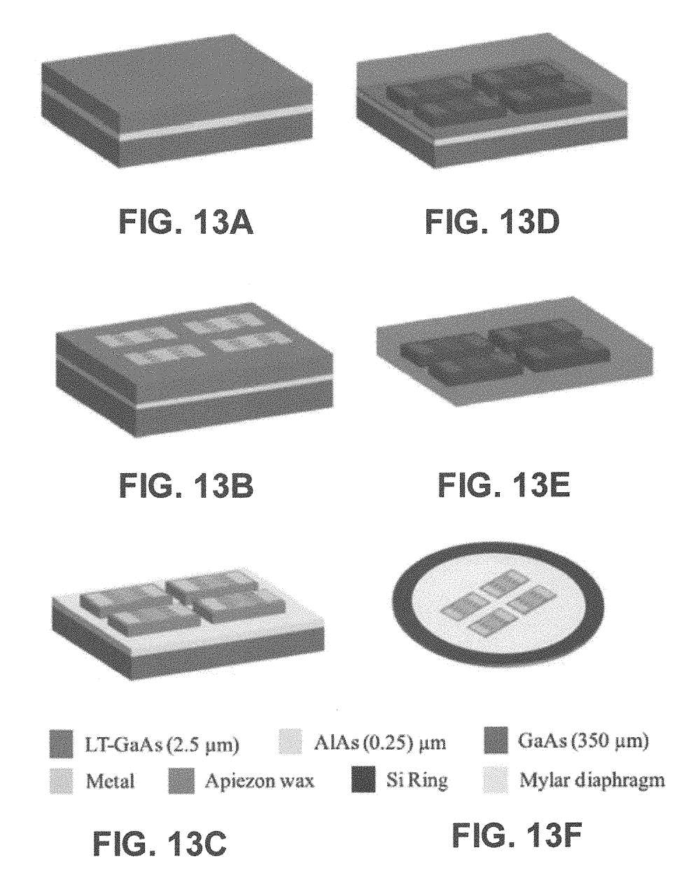

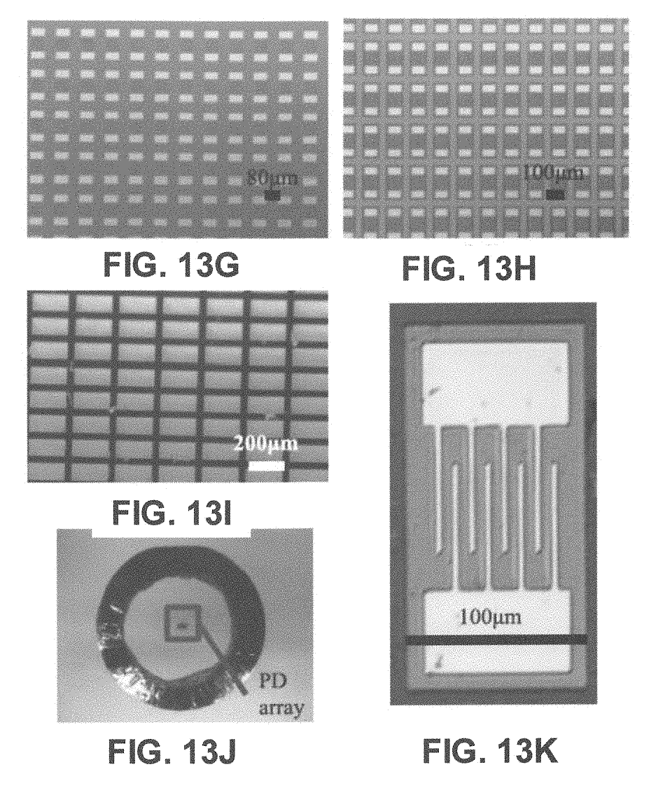

LT-grown GaAs based thin-film inverted MSM photodetectors were fabricated in their suitable growth substrate. The starting wafer for the device fabrication consisted of the following layers: LT-grown GaAs device layer/AlAs sacrificial layer/semi-insulating GaAs growth substrate with thickness of 2.5 μm/0.25 μm/350 μm (FIG. 13A). The metal patterning for the PDs were done by a dual layer lift-off process comprising of dual layer photolithography (AZ5214 and SF11) and thermal evaporation. The interdigitated finger pattern of the PDs was defined using gold/nickel/chrome (Au/Ni/Cr) with thickness of 180 nm/100 nm/20 nm respectively (FIG. 13B and FIG. 13G). The influence of nickel layer on the PD performance is acceptable and 100 nm of the nickel is sufficient to pick up the thin-film device in water with a magnetized needle tip. Using a citric acid and hydrogen peroxide (4:1) solution, wet etching was carried out to define the device mesa with dimensions of 100 μm×200 μm (FIG. 13C, 13H)). Next, the thin-film devices were embedded and protected by an APIEZON® W wax (FIG. 13D), followed by the removal of the AlAs sacrificial layer using hydrofluoric acid (HF, 10%) (FIG. 13E). Thus, the device layer (LT-grown GaAs) was detached from the growth substrate and an array of the PDs is shown in FIG. 13I. A Mylar diaphragm was prepared by stretching and bonding a Mylar film onto a silicon ring. The devices embedded in APIEZON® wax were attached onto the Maylar diaphragm using a water droplet and left overnight to assure the adhesion between the devices and the diaphragm. Then, the wax was removed by trichloroethylene (TCE) and the fabrication results are shown in FIG. 13J, FIG. 13K). The final thickness of the PDs is about 2.3 μm.

Host Substrate Preparation

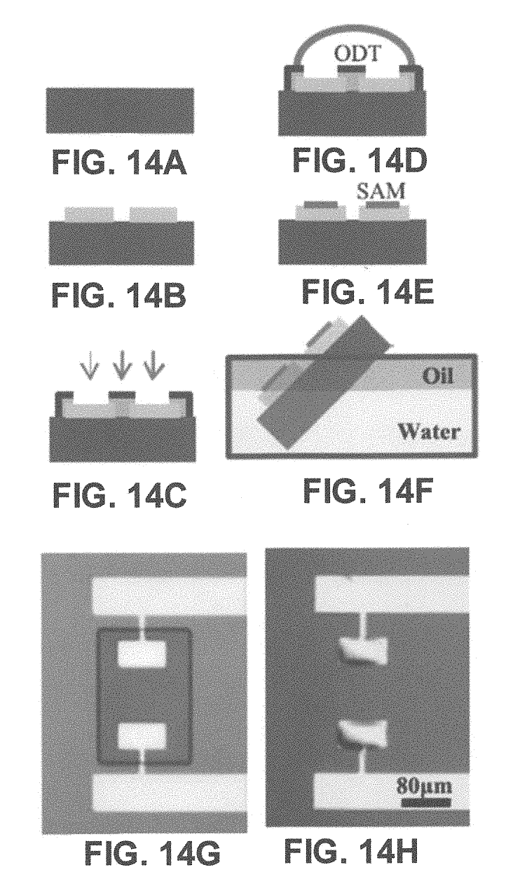

The host substrate used for this work is a 1 μm thick silicon dioxide thermally grown silicon wafer (FIG. 14A). A metal (Au/Cr, 180 nm/20 nm) layer was patterned using same dual layer lift-off process (FIG. 14B). The binding sites were opened by the dual layer photolithography with AZ5214 and SF11 photoresists. After the removal of the first layer of the photoresist (AZ5214) using acetone and IPA, oxygen (O₂) plasma was used to selectively modify the surface of gold binding sites making it highly hydrophilic (FIG. 14C, FIG. 14G). This benefits the formation of self-assembled monolayer (SAM) on the binding sites. Because one terminal of the SAM adheres well onto the hydrophilic gold surface, while the other terminal is hydrophobic. An 1mM ODT solution (1-octadecanethiol in ethanol, CH₃(CH₂)₁₇SH, Sigma-Aldrich) was employed to cover the sample surface to form the self-assembled monolayer (FIG. 14D). The substrate was then immersed into PG remover to strip off SF11 followed by cleaning with acetone, methanol and IPA (FIG. 14E), and dried with nitrogen (N₂). The substrate was passed through a lubricant-water interface (FIG. 14F), and the lubricant formed only on the binding sites for integration while the other gold areas remained untouched as shown in FIG. 14H. The lubricant, employed here, is OPTICLEAR® S2 (National Diagnostics), which works as an attracting medium for the device releasing step during the integration and can be evaporated easily without leaving a trace on the host substrate.

Integration

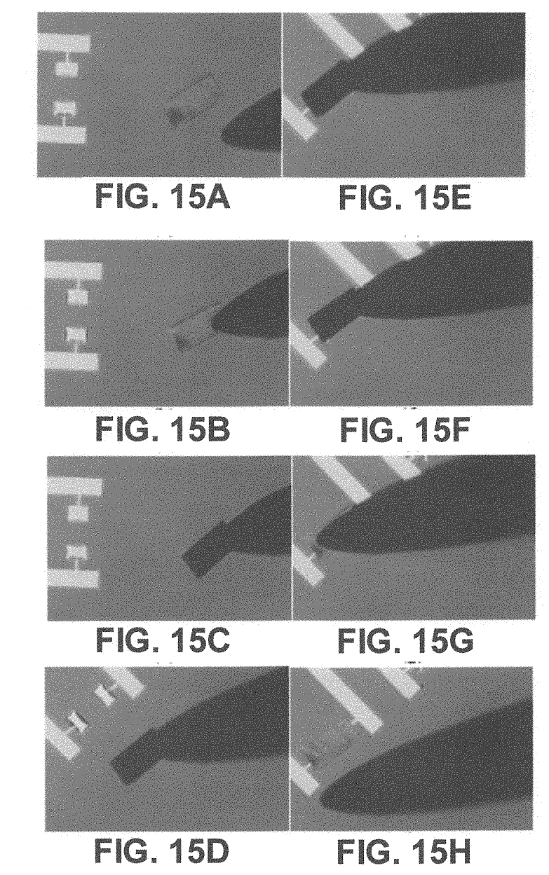

The integration initiated from the introduction of the magnetized CS needle to close proximity of thin-film PD immersed in fluidic environment (FIG. 15A). The ultrathin device was transferred from the Mylar diaphragm onto the silicon host substrate, which had lubricant on the predesigned binding sites. The needle having magnetic flux density of 5 mT measured at the tip was carefully lowered to make contact with the thin-film device (FIG. 15B). Once the contact happened, the magnetized tip was lifted up and as a result the devices got picked up by overcoming the adhering forces between the thin-film PD and its host substrate (FIG. 15C). For more convenient manipulation, the host substrate was roughly aligned in parallel to the movement direction of the needle (FIG. 15D). Next, the device was brought and aligned coarsely onto the top of binding sites (FIG. 15E), followed by the releasing of the thin-film PD (FIG. 15F to FIG. 15H). Once the PD came into contact with the lubricant, it was attracted by the lubricant due to the capillary force and got released from the tip. This capillary force between the device and lubricant is much stronger than the magnetic force between the tip and device. Here, one side of the device was in contact with the lubricant at first, while the other side was still floating on top of the lubricant (FIG. 15F). By moving the contact needle across the device's lateral dimension, the floating end was made in contact with the other half of the lubricant-coated integration pad (FIG. 15G). The integration result is shown in FIG. 15H after the needle was lifted up and moved away.

Self-Alignment of the Device

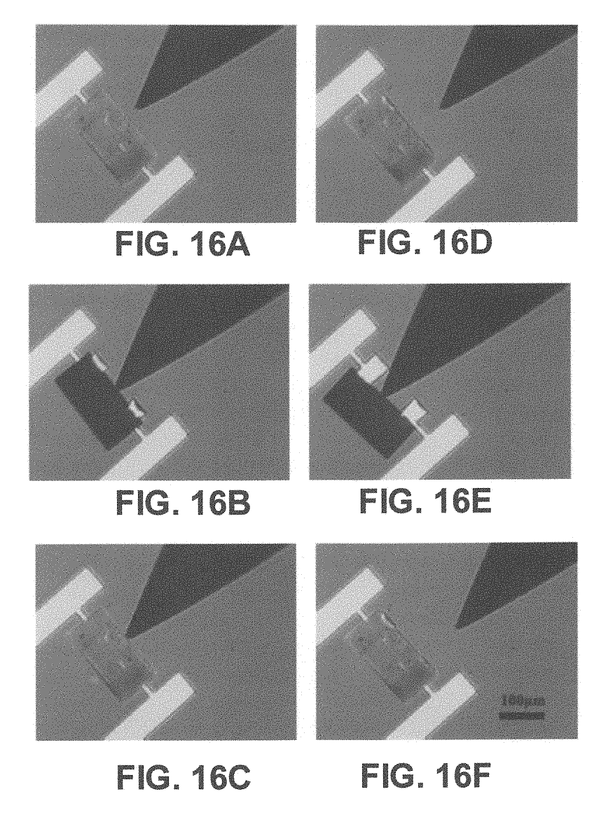

Self-alignment is one of the most attractive aspects of fluidic self-assembly. A fine probe tip was employed to create a lateral displacement of the integrated device to demonstrate its capability of self-alignment (FIG. 16A to FIG. 16F). In water, the integrated PD was moved away from its original location (see FIG. 16A and FIG. 16D) using the probe tip and misalignment was generated between the PD and predesigned binding sites (FIG. 16B, FIG. 16E). When the probe tip was moved back, the PD returned to the initial position automatically due to the interfacial energy minimization (FIG. 16C, FIG. 16F)). As shown in FIG. 16D, FIG. 16E and FIG. 16F, the PD still self-aligned onto its original location even when the displacement is greater than 45 μm, which is more than the half length of the binding sites (length x width, 80 μm×45 μm).

Alignment Accuracy and Electrical Characteristic of the Integrated PD

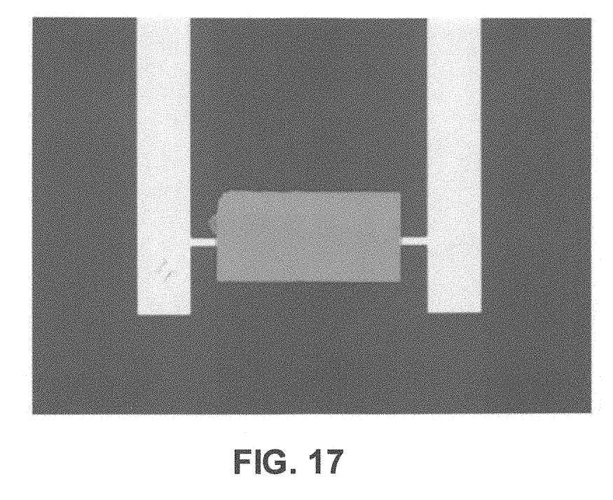

After the integration was completed, a series of post-processing steps were carried out to make a stable metal-to-metal contact between the PD and binding sites on host substrate. The water for the integration was drained out, and the sample was placed in an oven to evaporate the lubricant completely. FIG. 17 shows the SEM (Scanning Electron Microscope) micrograph of the integrated device. The misalignment was calculated to be 1.4 μm and 6.2 μm for X and Y orientations, respectively. To achieve more precise alignment of the PD on the desired locations, various parameters should be carefully considered and designed. For example, these include the amount and viscosity of lubricant, the surface treatment, and the shape and quality of the integration pads.

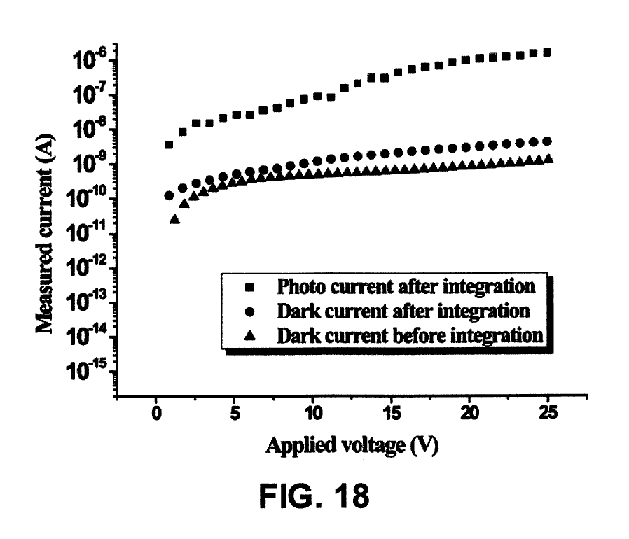

A Keithley 2400 SMU (source measurement unit) and a wafer probe station were used for the measurement of dark current and photo current of the PD to verify the electrical contact of the device and substrate (FIG. 18). The results demonstrate the effectiveness and functionality of the proposed integration method for the ultrathin device. Slight increase in the dark current was noticed after integration, which may result from the metallic bonding process.

Magnetization of CS Needle Tip for the Proposed Integration

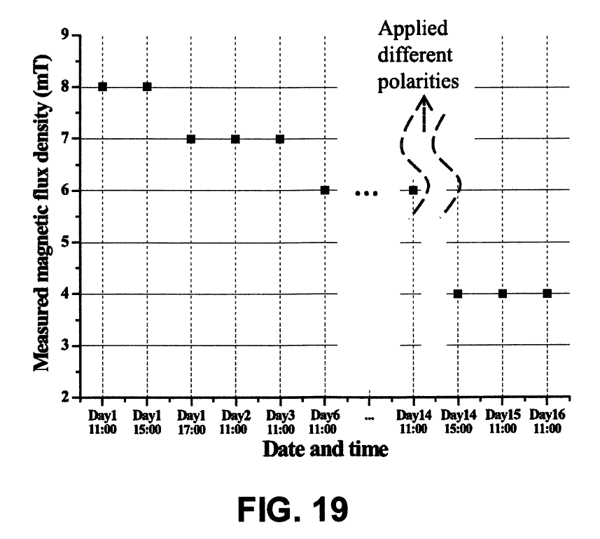

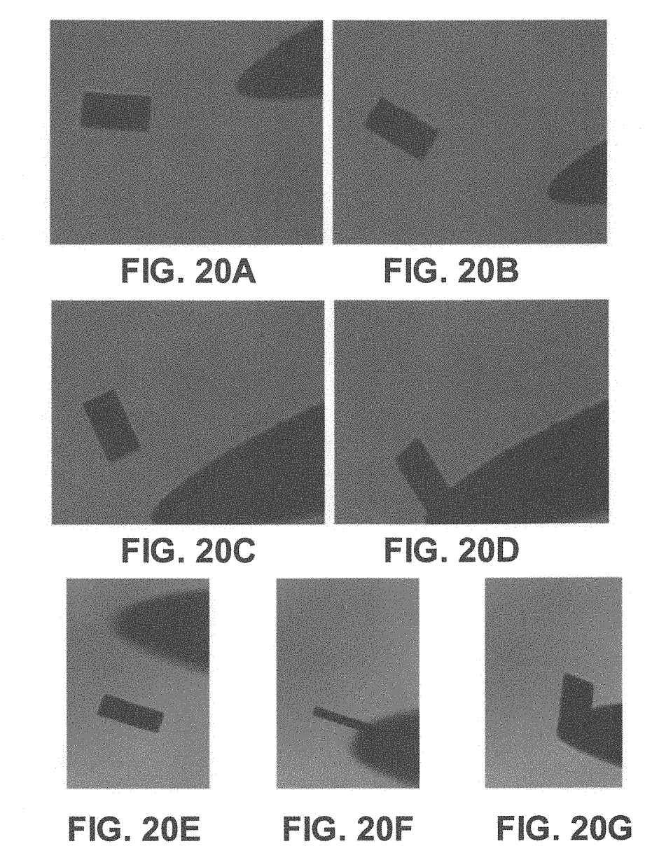

For a stable PAP process, it is desirable to produce a proper magnetic force at the CS needle tip by modifying its properties. While weak magnetic force cannot pick up a thin-film device, much stronger magnetic force causes jumping of the device during the pick-up step. The CS needle tip was magnetized by a magnetic cylinder (N52, NdFeB from K&J Magnetics, with dimensions ⅛″× 1/16″) for several days. After separating them, the magnetic flux density at the needle tip was measured by a portable digital Tesla meter (model No. HT20@Shanghai Huntoon Magnetic Technology Co., Ltd). The needle tip was brought into contact with the effective sensor head to obtain its magnetic flux intensity value. The magnitude of the induced magnetic field at the tip can be controlled by changing the orientation of the attached cylindrical permanent magnet. For example, the tip with 6mT can be adjusted to 4mT by applying different polarities of the permanent magnet as shown in FIG. 19. Also, the separated magnetized CS tip demonstrates certain value of the magnetic flux density for a long time (FIG. 19), for example, 6 mT can be maintained for more than a week and 4 mT for at least two days without showing any signs of degradation. This enables the repeated use of the magnetized tip. It was experimentally observed that 4-5 mT is the optimized magnetic field density at the tip to pick up a thin-film device from the substrate repeatedly and reliably, having little effect on the releasing step due to the much stronger capillary force. However, the needle tip with 6mT magnetic flux density caused slight jumping of the thin-film device (FIG. 20A, FIG. 20B, FIG. 20C and FIG. 20D). Even a higher magnetic flux density of 8mT at the micromanipulator tip induced more random device attachment as shown in FIG. 20E, FIG. 20F and FIG. 20G. FIGS. 20A to 20D show the magnetized CS tip with magnetic flux density of 6 mT (PD and CS tip are on the same focus plane). FIG. 20A shows the initial state. FIG. 20B and 20C show PD rotated as tip moved. FIG. 20D shows PD got attracted and adhered to CS tip when the tip was moved closer. FIG. 20E to 20G depicts the magnetized CS tip with magnetic flux density of 8mT. FIG. 20E shows the initial state. FIG. 20G depicts PD tilted vertically. FIG. 20G shows PD demonstrated more aggressive motion and got stuck to CS tip when the tip was lowered.

Device Storage in Water and Pick-Up Step

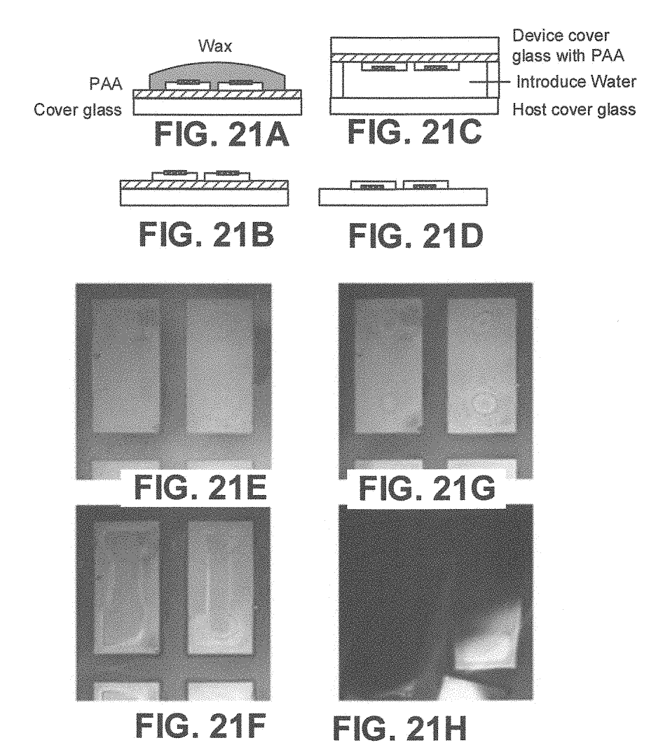

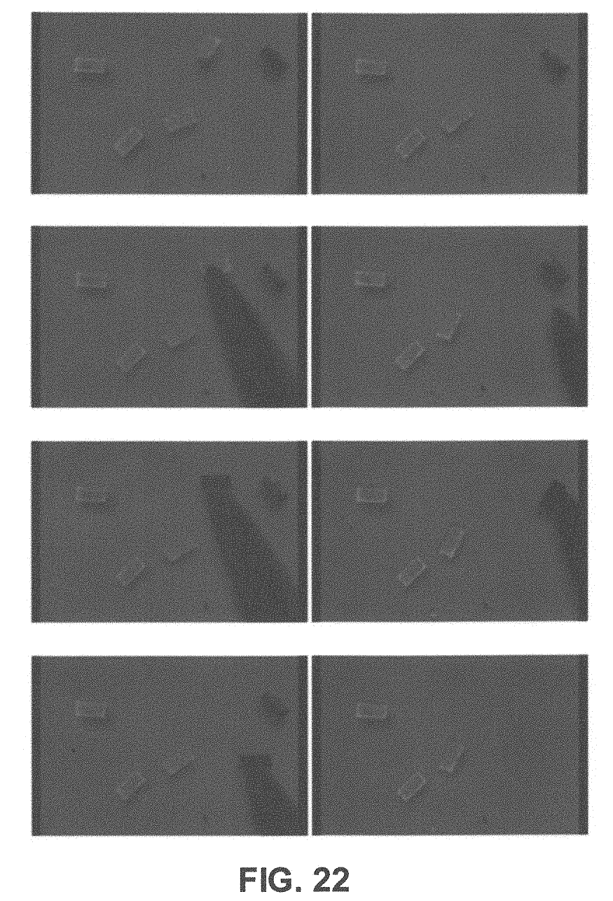

This integration process can be further developed by saving the thin-film device array on a substrate in water environment instead of the Mylar diaphragm. Subsequently, with advance automation strategies, the proposed integration approach can directly pick up devices, transport them to the host substrate, and place the devices onto their binding sites and complete the integration. This can be done with help of a water soluble polymer polyacrylic acid (PAA). A droplet of a solution comprising 25% Polyacrylic acid (PAA) and water (1:3 v/v) was dispensed onto a cover glass, and the devices protected by APIEZON® wax were placed on top of the PAA for overnight (FIG. 21A). Next, the wax was removed by Trichloroethylene (TCE) (FIG. 21B). Then, the devices on the PAA were transferred to another cover glass with their metal-side facing down for future integration. The setup is illustrated in FIG. 21C. The glass with PAA and devices was flipped over and mounted on top of the final host cover glass in a petri dish. DI water was then introduced with a pipette to the petri dish to dissolve the PAA (FIG. 21E, FIG. 21F, FIG. 21G), and thereby PDs got detached from the upper cover glass (FIG. 21H). The PDs were saved and stored on the host cover glass in the water environment for future integration approach.

The picking-up of these devices from host cover glass was also studied by the magnetized needle tip with magnetic flux density 4-5 mT (FIG. 22). The tip was moved to contact one device at a time and pick it up to transfer it into the integration space. The release and storage steps of micro devices in water will be further studied more systematically to analyze the overall integration throughput.

Force Balancing Analysis for Device's PAP

Simulations were preformed to provide a quantitative comparison between the forces involved in the integration technique. The forces taking into consideration were the attractive magnetic force between the magnetized needle tip and the thin-film device (F_{magnetic(device & needle tip)}), the capillary force between device and lubricant (F_{capillary(device and lubricant)}).

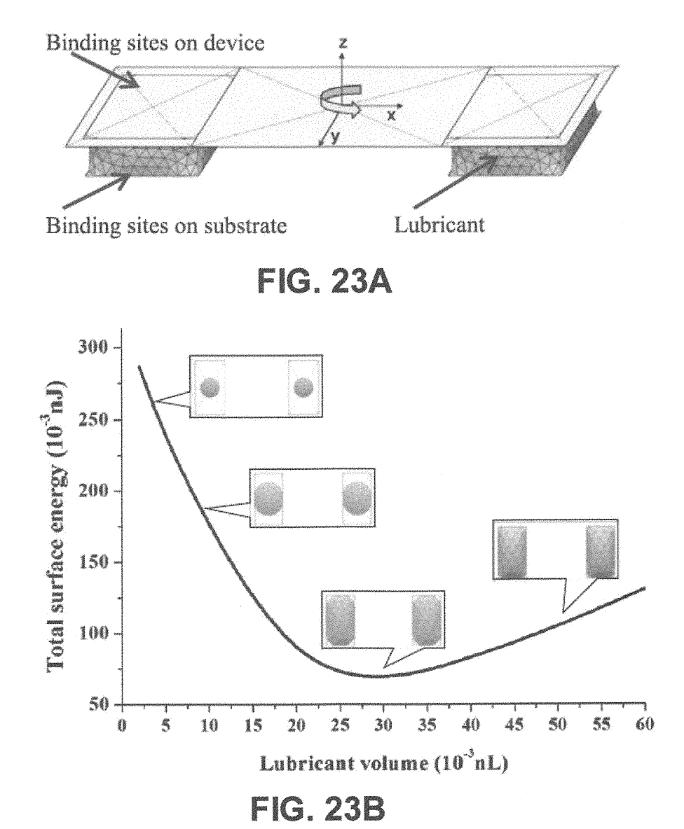

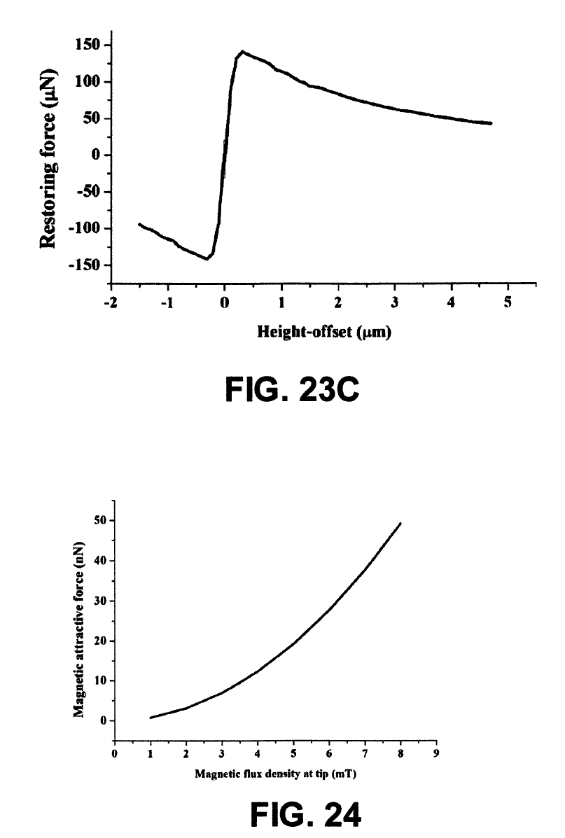

Numerical simulations for restoring capillary forces between the device and lubricant were performed with help of SURFACE EVOLVER software. Values for different parameters were taken from the literature. The surface energies considered are 53.3 mJ/m², 47 mJ/m², and 1 mJ/m² for the interface of lubricant-water, SAM-water, and lubricant-SAM, respectively. The area of the binding sites is 45 μm×80 μm and dimension of the device is 200 μm×100 μm×2 μm. FIG. 23A illustrates the simulation model and structure. The optimal lubricant volume for the designed binding sites and the height of lubricant between device and substrate for minimum energy state were initially studied as shown in FIG. 23B and FIG. 23C respectively. From the simulation, it can be seen that the optimal lubricant volume is 30.2 μL. Assuming the restoring force for lifting up the device in the simulation is similar to the capillary force to detach the device from the magnetized needle tip in the actual releasing step, the capillary force can be estimated to be about 50 μN for Z-offset of 4 μm.

FIG. 24 depicts the variation of the attractive magnetic force with increasing magnetic flux density at the needle tip having diameter of 50 μm. The attractive magnetic force exerted by the magnetized needle tip to the thin-film device can be calculated as:

F=0.577·B²·A (1)

where F represents the attractive magnetic force, B represents the induced magnetic flux density and A represents the magnetized needle tip pole area. It can be observed from FIG. 24 that for the optimized induced magnetic flux density of 4-5 mT, the magnetic attractive force between the needle tip and the micro device is estimated to be 12-19 nN.

From the above force calculations, it can be concluded that during the device releasing step, the capillary force between the device and lubricant (F_{capillary(device and lubricant)}) is considerably greater than the attractive magnetic force between the magnetized needle tip and the thin-film device (F_{magnetic (device & needle tip)}). Also it can be shown that magnetic attractive force is larger compared to the reported experimental values of adhesive force between different flat surfaces under water ensuring safe handling of ultrathin devices during pickup step.

Restoring Forces for Planar Displacement

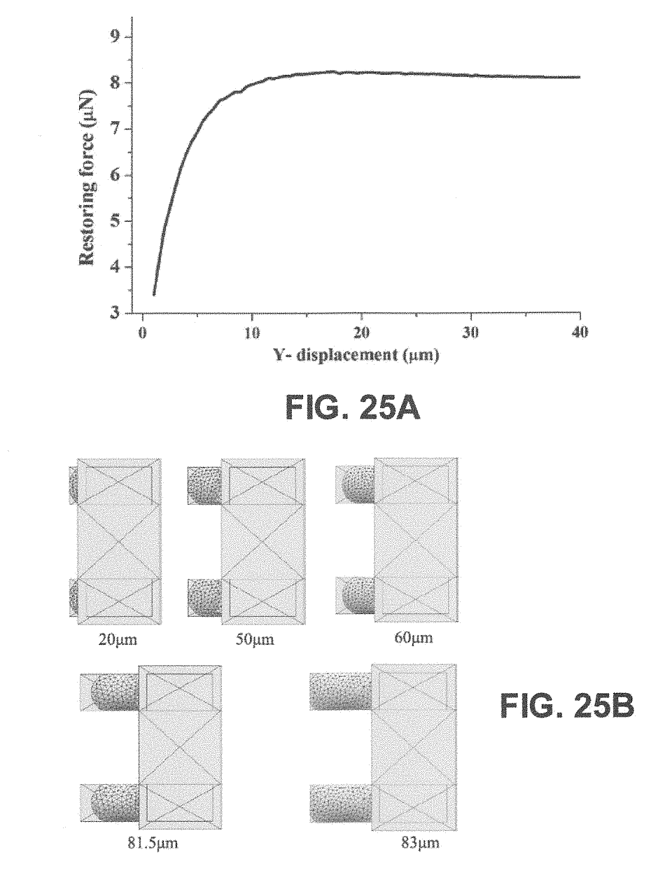

The SURFACE EVOLVER was also employed to estimate the planar restoring force and investigate the possible maximum lateral displacement of the thin-film device for successful fluidic self-alignment. As shown in FIG. 25A, the capillary restoring force on the y-axis is calculated to be 8.23 μN at offset of 20 μm. The assembly configurations predicted by the software is shown in FIG. 25B. With height maintained at 4.19 μm, the y-offset is varied from 10 μm to 85 μm. The lubricant appears to be stable up to a lateral offset of 81.5 μm, but is unable to hold the micro device at the binding sites when the offset is increased to 83 μm. The simulated results for the maximum lateral displacement of the micro device from its optimal integration location are similar to the ones already demonstrated in literature. From the simulations, it can be concluded that the maximum allowable lateral offset for the thin-film device is around the length of the edge of binding sites for successful self-alignment.

Hydrodynamic Force Study

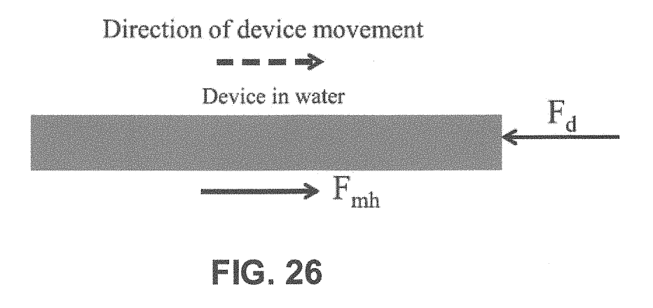

To discuss the maximum speed the tip can move in water when a device is loaded at a given magnetic flux density, the hydrodynamic force analysis was performed as simplified in FIG. 26. F_{d} represents the fluidic drag force due to the movement of device in water. Fₘₕ is the holding force of the device due to the magnetic force. The parallel magnetic holding force can be calculated by multiplying static friction coefficient with attractive magnetic normal force. Considering the value of coefficient of static friction to be 0.2, the parallel magnetic holding force (Fₘₕ) can be estimated as 2.4-3.8 nN for normal magnetic force (F_{magnetic(device & needle tip)} ranging 12-19 nN.

The fluidic drag force F_{d} can be calculated by

$$\begin{matrix}{F}_{d} = 0.5 \cdot {C}_{D} \cdot {A}_{D} \cdot {ρ}_{ω} \cdot {v}^{2} & ( 2 ) \\ {C}_{D} = \frac{4 π}{( {R}_{e} \cdot ln ( \frac{24.4}{{R}_{e }} ) )} , {R}_{e} < 1 & ( 3 ) \\ {R}_{e} = {ρ}_{ω} \cdot v \cdot L / {μ}_{ω} & ( 4 )\end{matrix}$$

where C_{D} is the drag coefficient for a flat surface, A_{D} is the characteristic area of the device (200 μm×100 μm), ρ_{ω} is the density of water (999.73 kg/m³) and ν is the average velocity, Rₑ is Reynolds number and C_{D} is obtained by the empirical expression of Rₑ, L is the characteristic linear dimension (100 μm), and μ_{ω} is the water viscosity (1.002×10⁻³ Pa·s at temperature 20° C.). Considering the motion is overdamped, i.e. the viscous time scale largely exceeds the inertial time scale, the maximum average velocity of the magnetized needle in water can be calculated as 6.8-9.7 mm/sec based on the above equations and the estimated holding force.

A technique for the integration of an ultrathin device onto a silicon based host substrate has been reported in this work. Magnetic-field-based modified PAP method was utilized to guide the micro devices close to the integration site and surface tension driven fluidic self-assembly was employed to release and self-align the devices onto their predefined binding areas. Different aspects of the process starting from device fabrication, host substrate preparation, PAP tool modification have been described in details. LT-grown GaAs based MSM PDs fabricated in its optimized growth substrate and fabrication procedures have been used for the self-assembly. Surface wetting properties of a silicon dioxide thermally grown silicon wafer was selectively modulated to create the binding sites on the host substrate. Photocurrent and dark current measurements were performed on the integrated device to confirm the electrical contact between the device and the integration pads. This hybrid integration method sustains the advantages of both fluidic self-assembly and robotic PAP, thus providing an attractive alternative as a low cost technique for the integration of ultra-thin devices.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method for self-aligning a thin-film device on a host substrate, the method comprising steps of:
preparing a host substrate by depositing a first hydrophobic lubricant on at least one predetermined location on the host substrate;
releasing a thin-film device under water from a carrier substrate, wherein the thin-film device is attached to the carrier substrate by a water-soluble polymer;
picking up the thin-film device with a hydrophobic needle having a second hydrophobic lubricant at a tip of the hydrophobic needle;
moving, while in a water environment, the hydrophobic needle with the thin-film device to the host substrate and contacting the thin-film device to the first hydrophobic lubricant on the predetermined location of the host substrate, the step of moving occurring with the thin-film device, the host substrate and the hydrophobic needle are under water;
permitting the thin-film device to adhere and self-align with the predetermined location due to interfacial energy minimization; and
evaporating the first hydrophobic lubricant.

2. The method as recited in claim 1, wherein the host substrate comprises silicon dioxide coated silicon.

3. The method as recited in claim 1, wherein the thin-film device is a photonic device.

4. The method as recited in claim 3, wherein the thin-film device comprises gallium Arsenic.

5. The method as recited in claim 1, wherein predetermined location comprises a gold surface that is coated with an aliphatic thiol.

6. The method as recited in claim 1, wherein the hydrophobic needle comprises a gold tip and a hydrophobic thiol layer on the gold tip.

7. The method as recited in claim 1, further comprising exposing the hydrophobic needle to the second hydrophobic lubricant, the step of exposing occurring after the step of preparing and prior to the step of moving.

8. The method as recited in claim 7, wherein the second hydrophobic lubricant comprises a hydrocarbon blend.

9. The method as recited in claim 1, further comprising exposing the hydrophobic needle to the second hydrophobic lubricant to form a hydrophobic droplet on the hydrophobic needle.

10. The method as recited in claim 1, wherein the thin-film device is less than or equal to 200 μm long, less than or equal to 100 μm wide and less than 5 μm thick.

11. A method for self-aligning a thin-film device on a host substrate, the method comprising steps of:
preparing a host substrate by depositing a hydrophobic lubricant on at least one predetermined location on the host substrate;
picking up the thin-film device with a magnetic needle;
moving, while in a water environment, the magnetic needle with the thin-film device to the host substrate, and contacting the thin-film device to the hydrophobic lubricant on the predetermined location of the host substrate, the step of moving occurring with the thin-film device, the host substrate and the magnetic needle are under water;
permitting the thin-film device to adhere and self-align with the predetermined location due to interfacial energy minimization; and
evaporating the hydrophobic lubricant.

12. The method as recited in claim 11, wherein the magnetic needle has a magnetic flux density of between 4 mT and 5 mT.

13. The method as recited in claim 11, wherein the host substrate comprises silicon dioxide coated silicon.

14. The method as recited in claim 11, wherein the thin-film device is a photonic device.

15. The method as recited in claim 14, wherein the thin-film device comprises gallium Arsenic.

16. The method as recited in claim 11, wherein predetermined location comprises a gold surface and the hydrophobic lubricant is a hydrocarbon blend.

17. The method as recited in claim 11, within the thin-film device is less than or equal to 200 μm long, less than or equal to 100 μm wide and less than 5 μm thick.
